(19) United States
(12) Patent Application Publication
(10) Pub. No.: US 2024/0339376 A1
(43) Pub. Date: Oct. 10, 2024

(54) CHIP ON FILM PACKAGE AND METHOD OF MANUFACTURING THE CHIP ON FILM PACKAGE

(71) Applicant: SAMSUNG ELECTRONICS CO., LTD., Suwon-si (KR)

(72) Inventors: Seunghyun CHO, Suwon-si (KR); Eunho CHO, Suwon-si (KR)

(21) Appl. No.: 18/403,864

(22) Filed: Jan. 4, 2024

(30) Foreign Application Priority Data
Apr. 10, 2023 (KR) 10-2023-0046746

(51) Int. Cl. H01L 23/373; H01L 21/48; H01L 23/00; H01L 23/498

(52) U.S. Cl. CPC H01L 23/373; H01L 21/481; H01L 23/4985; H01L 24/16; H01L 24/32; H01L 24/73; H01L 23/145; H01L 2224/16227; H01L 2224/32225; H01L 2224/73204

(57) ABSTRACT

A chip on film package includes a flexible base film having a first surface and a second surface opposite to the first surface, the base film having a chip mounting region on the first surface; a plurality of wirings extending from the chip mounting region on the first surface of the base film in a first direction parallel to an extending direction of the base film; a semiconductor chip mounted on the chip mounting region on the first surface of the base film and electrically connected to the plurality of wirings; a heat dissipation layer provided to have a predetermined thickness in a depth direction from the second surface of the base film in an area overlapping the chip mounting region, the heat dissipation layer including a laser-induced carbon material; and an insulating layer covering the heat dissipation layer on the second surface of the base film.

### CROSS-REFERENCE TO RELATED APPLICATION

This application claims priority under 35 U.S.C. § 119 to Korean Patent Application No. 10-2023-0046746, filed on Apr. 10, 2023, in the Korean Intellectual Property Office (KIPO), the contents of which are herein incorporated by reference in their entirety.

### BACKGROUND

### 1 Field

Example embodiments relate to a chip on film package and a method of manufacturing the chip on film package. More particularly, example embodiments relate to a chip on film package connected to a display panel and a method of manufacturing the same.

### 2. Description of the Related Art

In a tape carrier package (TCP) technology, in which an integrated circuit (IC) chip is mounted in a tape-shaped package, a chip on film (COF) package was developed to respond to the miniaturization trend of a light and thin electronic device, e.g., a display. Recently, with the development of high-spec panels, IC power consumption has increased and higher heat dissipation performance is desired.

### SUMMARY

According to example embodiments, a chip on film package may include a flexible base film having a first surface and a second surface opposite to the first surface, the base film having a chip mounting region on the first surface; a plurality of wirings extending from the chip mounting region on the first surface of the base film in a first direction parallel to an extending direction of the base film; a semiconductor chip mounted on the chip mounting region on the first surface of the base film and electrically connected to the plurality of wirings; a heat dissipation layer provided to have a predetermined thickness in a depth direction from the second surface of the base film in an area overlapping the chip mounting region, the heat dissipation layer including a laser-induced carbon material; and an insulating layer covering the heat dissipation layer on the second surface of the base film.

According to example embodiments, a chip on film package may include a flexible base film having a chip mounting region, the base film having first and second surfaces opposite to each other, the base film extending in a first direction, a plurality of wirings provided on the first surface of the base film, each of the plurality of wirings having an inner lead bonding portion disposed in the chip mounting region; a protective layer covering at least portions of the plurality of wirings on the first surface of the base film, the protective layer having a mounting region opening that exposes the chip mounting region; a semiconductor chip disposed on the chip mounting region on the first surface of the base film and mounted on the inner lead bonding portions via conductive bumps; a heat dissipation layer provided to have a predetermined thickness in a depth direction from the second surface of the base film in an area overlapping the chip mounting region, the heat dissipation layer including a laser-induced carbon material; and an insulating layer covering the heat dissipation layer on the second surface of the base film.

According to example embodiments, a chip on film package may include a flexible base film having a first surface and a second surface opposite to the first surface, the base film extending in a first direction, the base film having a chip mounting region that extends in a second direction perpendicular to the first direction, the base film having a first side surface and a second side surface extending in a direction parallel to the second direction and facing each other; a plurality of wirings provided on the first surface of the base film, each of the plurality of wirings including an inner lead bonding portion disposed in the chip mounting region and an outer lead bonding portion disposed in at least one of the first side surface and the second side surface; a protective layer covering at least portions of the plurality of wirings on the first surface of the base film, the protective layer having a mounting region openings that exposes the chip mounting region and pad openings that expose the outer lead bonding portions; a semiconductor chip disposed on the chip mounting region on the first surface of the base film and mounted on the inner lead bonding portions via conductive bumps; a sealing member filling the mounting region opening of the protective layer and interposed between the semiconductor chip and the base film; a heat dissipation layer provided to have a predetermined thickness in a depth direction from the second surface of the base film in an area overlapping the chip mounting region, heat dissipation layer including laser-induced graphene; and an insulating layer covering the heat dissipation layer on the second surface of the base film.

### BRIEF DESCRIPTION OF THE DRAWINGS

Features will become apparent to those of skill in the art by describing in detail exemplary embodiments with reference to the attached drawings, in which:

FIG. 1 is a perspective view of a display device in accordance with example embodiments.

FIG. 2 is a cross-sectional view of a curved chip on film package of the display device in FIG. 1.

FIG. 3 is a plan view of a chip on film package in accordance with example embodiments.

FIG. 4 is a cross-sectional view taken along line A-A′ in FIG. 3.

FIG. 5 is a cross-sectional view taken along line B-B′ in FIG. 3.

FIGS. 6 to 13 are views of stages in a method of manufacturing a chip on film package in accordance with example embodiments.

FIG. 14 is a plan view of a heat dissipation layer having another shape of a chip on film package in accordance with example embodiments.

FIG. 15 is a plan view of a heat dissipation layer having another shape of a chip on film package in accordance with example embodiments.

### DETAILED DESCRIPTION

Hereinafter, example embodiments will be explained in detail with reference to the accompanying drawings. In all figures in this specification, directions indicated by an arrow and a reverse direction thereto are considered as the same direction.

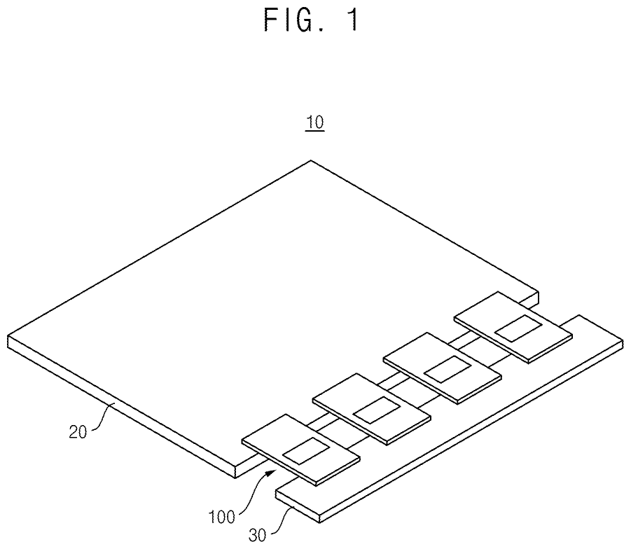

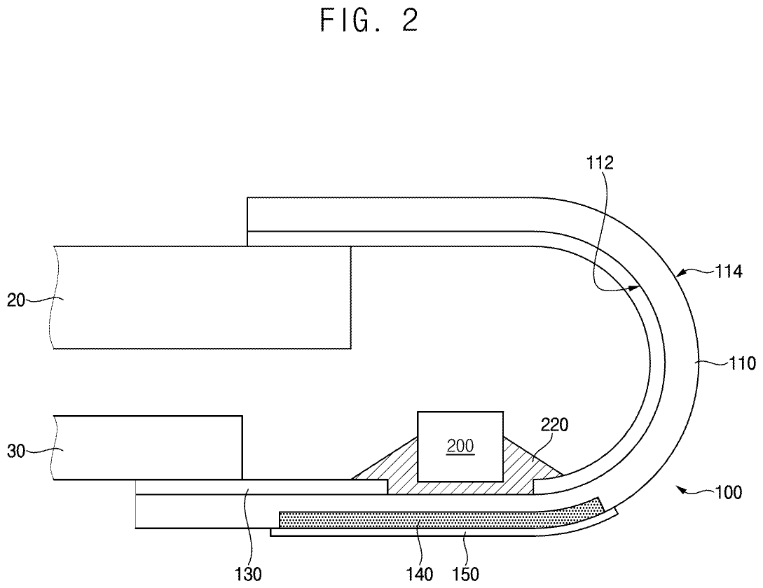

FIG. 1 is a perspective view illustrating a display device in accordance with example embodiments. FIG. 2 is a cross-sectional view illustrating a curved chip on film package of the display device in FIG. 1.

Referring to FIGS. 1 and 2, a display device 10 may include a display panel 20 displaying an image, a driving circuit portion 30 configured to supply a driving signal to the display panel 20, and a chip on film package 100 configured to electrically connect the display panel 20 and the driving circuit portion 30.

In example embodiments, the display panel 20 may be a device which displays an image by driving signals supplied from an external device. For example, the display panel 20 may include a liquid crystal display panel, an electrophoretic display panel, an organic light emitting diode panel, a plasma display panel, etc.

The driving circuit portion 30 may be electrically connected to the chip on film package 100. For example, the driving circuit portion 30 may be a printed circuit board. The driving circuit portion 30 may include a driving circuit configured to generate or transmit driving signals for driving the display panel 20. The driving circuit portion 30 may be provided as a portion of a main board.

The chip on film package 100 may transmit the driving signals supplied from the driving circuit portion 30 to the display panel 20. That is, the chip on film package 100 may electrically connect the driving circuit portion 30 and the display panel 20. A plurality of the chip on film packages 100 may be arranged along a side of the display panel 20.

In example embodiments, the chip on film package 100 may include a flexible base film 110. The base film 110 may have a first surface 112 and a second surface 114 opposite to the first surface 112. The base film 110 may be an insulating film having flexibility. For example, the base film 110 may include polyimide (PI), polyetheretherketone (PEEK), polyetherimide (PEI), polysulfone (PSU), lignin, etc.

A semiconductor chip 200 as a driving chip for a display panel may be mounted on the first surface 112 of the base film 110, and may be electrically connected to the display panel 20 through wirings on the base film 110.

As illustrated in FIG. 2, a first end portion of the chip on film package 100 may be connected to the display panel 20. A second end portion of the chip on film package 100 opposite to the first end portion may be connected to the driving circuit portion 30. The first surface 112 of the base film 110 may be connected to a front surface of the display panel 20. For example, the chip on film package 100 may be bent to surround one side (e.g., an edge) of the display panel 20 and cover a rear surface of the driving circuit portion 30. Accordingly, the first surface 112 of the base film 110 may face the front surface of the display panel 20 and the rear surface of the driving circuit portion 30. However, other connection structures between the base film 110, the display panel 20 (e.g., a touch panel), and the driving circuit portion 30 may be implemented.

As will be described below, the chip on film package 100 may include a heat dissipation layer 140 provided on the second surface 114 of the base film 110 to overlap the semiconductor chip 200, e.g., the heat dissipation layer 140 and the semiconductor chip 200 may be on opposite surfaces of the base film 110 while overlapping each other. The heat dissipation layer 140 may include a laser-induced carbon material formed on the second surface 114 of the base film 110 by laser scribing. Since the heat dissipation layer 140 has relatively high thermal conductivity and flexibility of a polymer, it may provide higher heat dissipation characteristics, various shapes, and a high degree of design freedom, and prevent defects from being peeled off from the bent base film 110.

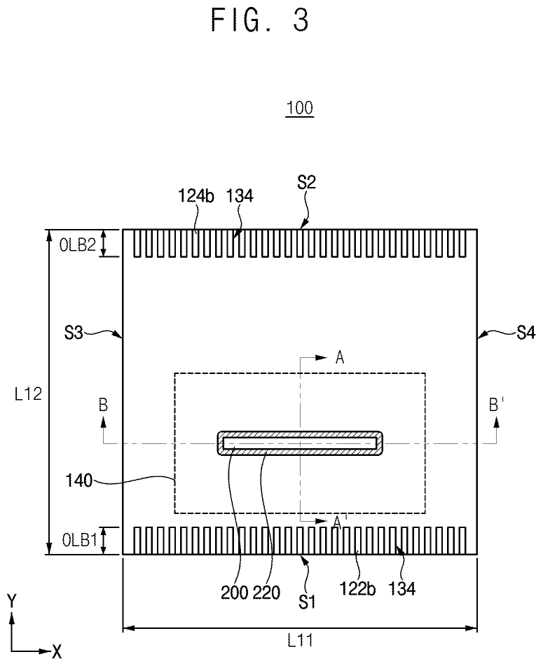

Hereinafter, the chip on film package will be described in detail with reference to FIGS. 3-5.

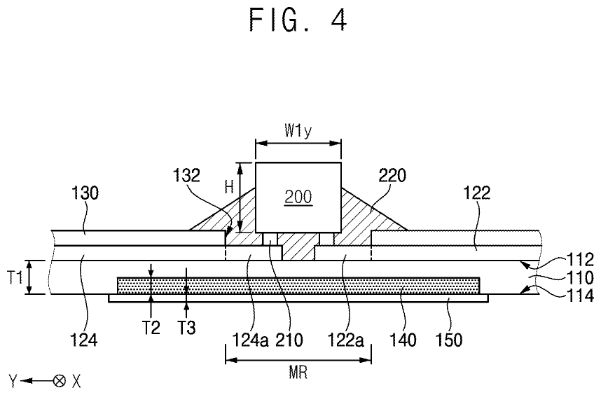

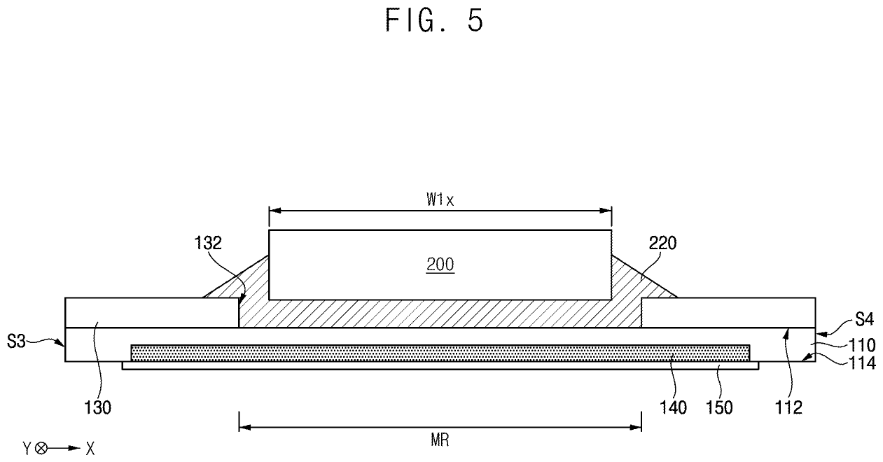

FIG. 3 is a plan view illustrating the chip on film package 100 in accordance with example embodiments. FIG. 4 is a cross-sectional view taken along line A-A′ in FIG. 3. FIG. 5 is a cross-sectional view taken along line B-B′ in FIG. 3.

Referring to FIGS. 3 to 5, the chip on film package 100 may include the flexible base film 110, a plurality of wirings 122 and 124, a protective layer 130, the heat dissipation layer 140, an insulating layer 150, and the semiconductor chip 200. Additionally, the chip on film package 100 may further include conductive bumps 210 and a sealing member 220.

In example embodiments, the base film 110 may have the first surface 112 and the second surface 114. The base film 110 may have a rectangular shape extending in a first direction (X direction). The base film 110 may have a first side surface S1 and a second side surface S2 extending in a direction parallel to the first direction (X direction) perpendicular to a second direction and facing each other, and a third side surface S3 and a fourth side surface S4 extending in the second direction (Y direction) and facing each other.

A width L11 in the first direction of the base film 110 may be within a range of 20 mm to 80 mm. A width L12 in the second direction of the base film 110 may be within a range of 20 mm to 50 mm. For example, the base film 110 may have a shape in which the width L11 in the first direction is greater than the width L12 in the second direction. A thickness T1 of the base film 110 may be within a range of 20 μm to about 40 μm.

The base film 110 may include a chip mounting region MR, a first outer terminal region OLB1, and a second outer terminal region OLB2. The chip mounting region MR may be located in the center of the base film 110 and may be an area where the semiconductor chip 200 is mounted. The first outer terminal region OLB1 may be an area extending along the first side surface S1 of the base film 110, and the second outer terminal region OLB2 may be an area extending along the second side surface S2 of the base film 110. For example, the chip mounting region MR may be between the first outer terminal region OLB1 and the second outer terminal region OLB2.

The plurality of wirings 122 and 124 may be provided on the first surface 112 of the base film 110. The plurality of wirings may include a plurality of input wirings 122 and a plurality of output wirings 124. The input wirings 122 and the output wirings 124 may extend from the inside to the outside of the chip mounting region MR. The input wirings 122 may extend from the chip mounting region MR to the first outer terminal region OLB1 along the extending direction (Y direction) of the base film 110, i.e., in the second direction. The output wirings 124 may extend from the chip mounting region MR to the second outer terminal region OLB2 along the second direction of the base film 110. The input wirings 122 and the output wirings 124 may be spaced apart from each other along the first direction (X direction) perpendicular to the extending direction (Y direction) of the base film 110.

The input wiring 122 may include an input inner lead bonding portion 122a disposed in the chip mounting region MR and an input outer lead bonding portion 122b disposed in the first outer terminal region OLB1. The output wiring 124 may include an output inner lead bonding portion 124a disposed in the chip mounting region MR and an output outer lead bonding portion 124b disposed in the second outer terminal region OLB2.

At least portions of the input and output inner lead bonding portions 122a and 124a may be bonded to the conductive bumps 210 on terminals of the semiconductor chip 200 in the chip mounting region MR. At least portions of the input and output outer lead bonding portions 122b and 124b may serve as input pins IPIN and output pins OPIN, respectively, for transmitting and receiving electrical signals to and from the display panel 20 or the driving circuit portion 30. The input pins IPIN may be arranged along the first side surface S1 of the base film 110 in the first outer terminal region OLB1, and the output pins OPIN may be arranged along the second side surface S2 of the base film 110 in the second outer terminal region OLB2.

The protective layer 130 may be coated on the first surface 112 of the base film 110 to cover at least a portion of the plurality of wirings. For example, the protective layer 130 may include a solder resist. The protective layer 130 may have a mounting region opening 132 that exposes the chip mounting region MR on the first surface 112 of the base film 110 and pad openings 134 that expose the input and output outer lead bonding portions 122b and 124b.

Accordingly, at least a portion of the input inner lead bonding portion 122a of the input wiring 122 and the output inner lead bonding portion 124a of the output wiring 124 may be exposed by the mounting region opening 132 of the protective layer 130. At least portions of the input outer lead bonding portion 122b of the input wiring 122 and the output outer lead bonding portion 124b of the output wiring 124 may be exposed by the pad openings 134 of the protective layer 130.

The semiconductor chip 200 may be mounted on the chip mounting region MA on the first surface 112 of the base film 110. The semiconductor chip 200 may be a driving chip for a display panel. The semiconductor chip 200 may be electrically connected to the input wirings 122 and the output wirings 124 through the conductive bumps 210. The conductive bumps 210 on the terminals of the semiconductor chip 200 may be bonded to the at least portions of the input and output inner lead bonding portions 122a and 124a exposed by the mounting region opening 132 of the protective layer 130. For example, the semiconductor chip 200 may be bonded to the input and output inner lead bonding portions 122a and 124a by a thermal compression process.

The sealing member 220 may fill the mounting region opening 132 of the protective layer 130 on the first surface 112 of the base film 110, and may underfill a gap between the semiconductor chip 200 and the base film 110. The sealing member 220 may be interposed between the semiconductor chip 200 and the base film 110. For example, the sealing member 220 may include an epoxy material to reinforce the gap between the semiconductor chip 200 and the base film 110. For example, the sealing member 220 may include an epoxy molding compound (EMC). The sealing member 220 may include, e.g., epoxy resin, UV resin, polyurethane resin, silicone resin, silica filler, etc.

As illustrated in FIGS. 4 and 5, the semiconductor chip 200 may have a shape in which a width W1x in the first direction is greater than a width W1y in the second direction. For example, the width W1x in the first direction of the semiconductor chip 200 may be within a range of 1,500 μm to 3,500 μm. A width W1y in the second direction of the semiconductor chip 200 may be within a range of 800 μm to 1,500 μm. A height H of the semiconductor chip 200 may be within a range of 300 μm to about 500 μm.

In example embodiments, the heat dissipation layer 140 may be provided to have a predetermined thickness T2 in a depth direction from the second surface 114 of the base film 110. The heat dissipation layer 140 may be disposed in an area overlapping (e.g., vertically overlapping) the chip mounting region MR. At least a portion of the heat dissipation layer 140 may extend from the second surface 114 of the base film 110 by a preset depth, e.g., the heat dissipation layer 140 may extend within the base film 110 from the second surface 114 toward the first surface 112 to a preset depth having a thickness T2 smaller than the thickness T1 of the base film 110. For example, as illustrated in FIG. 4, the bottom surface of the heat dissipation layer 140 may be coplanar with the second surface 114 of the base film 110. At least a portion of the heat dissipation layer 140 may be positioned to overlap the chip mounting region MR, e.g., the heat dissipation layer 140 may vertically overlap the entire chip mounting region MR.

The heat dissipation layer 140 may include a laser-induced carbon material formed on the second surface 114 of the base film 110 by laser scribing. The laser-induced carbon material may include, e.g., laser-induced graphene, laser-induced graphite, and laser-induced carbon nanotubes. The thickness T2 of the heat dissipation layer 140 may be within a range of 10 μm to 100 μm. The heat dissipation layer 140 may have a thermal conductivity of 1,500 W/m·K.

Since the heat dissipation layer 140 is formed by irradiating a laser on the second surface 114 of the base film 110, the shape, size, thickness, electrical, mechanical and surface characteristics of the heat dissipation layer 140 may be determined by the type of laser and manufacturing parameters. Therefore, since the heat dissipation layer 140 has relatively high thermal conductivity and flexibility of the polymer, it provides higher heat dissipation characteristics, various shapes, and a high degree of design freedom, and may prevent defects from being peeled off from the bent base film 110.

The insulating layer 150 may cover the heat dissipation layer 140 on the second surface 114 of the base film 110. The insulating layer 150 may cover the entire surface of the heat dissipation layer 140, e.g., the insulating layer 150 may vertically overlap the entire bottom surface of the heat dissipation layer 140. The insulating layer 150 may include, e.g., solder resist, polyimide, acrylic resin, epoxy resin, silicon material, etc. A thickness T3 of the insulating layer 150 may be within a range of 5 μm to 20 μm.

The lengths of the short and long sides of the base film 110, the size of the chip mounting region MR, and the size, thickness and shape of the heat dissipation layer 140 are provided as examples. The lengths of the short and long sides of the base film 110, the size of the chip mounting region MR, and the size, thickness, and shape of the heat dissipation layer 140 may be determined in consideration of the thickness, warpage, and heat dissipation characteristics of the entire chip on film package 100.

As mentioned above, the chip on film package 100 may include the semiconductor chip 200 mounted on the chip mounting region MR on the first surface 112 of the flexible base film 110 and the heat dissipation layer 140 provided to have a predetermined thickness T2 in the depth direction from the second surface 114 of the base film 110. The heat dissipation layer 140 may include laser-induced graphene formed on the second surface 114 of the base film 110 by laser scribing. Accordingly, since the heat dissipation layer 140 has relatively high thermal conductivity and flexibility of the polymer, it may be possible to provide higher heat dissipation characteristics, various shapes, and a high degree of design freedom, and to prevent the heat dissipation layer from being peeled off from the bent base film 110.

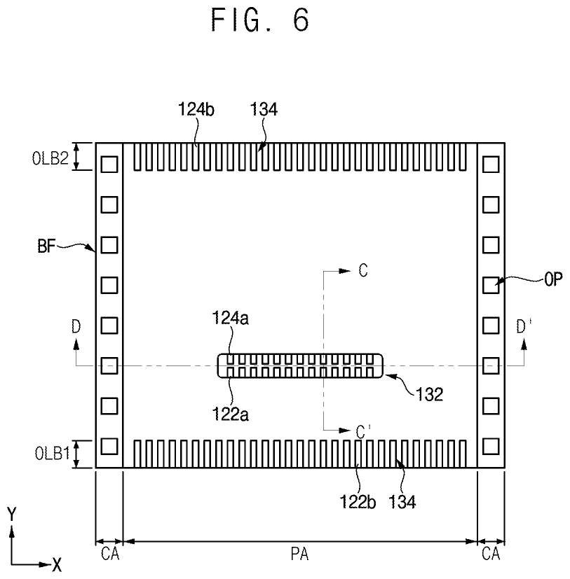

Hereinafter, a method of manufacturing the chip on film package 100 of FIG. 3 will be described with reference to FIGS. 6 to 13.

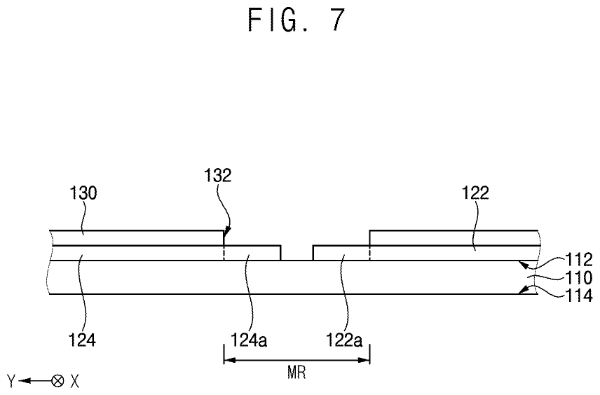

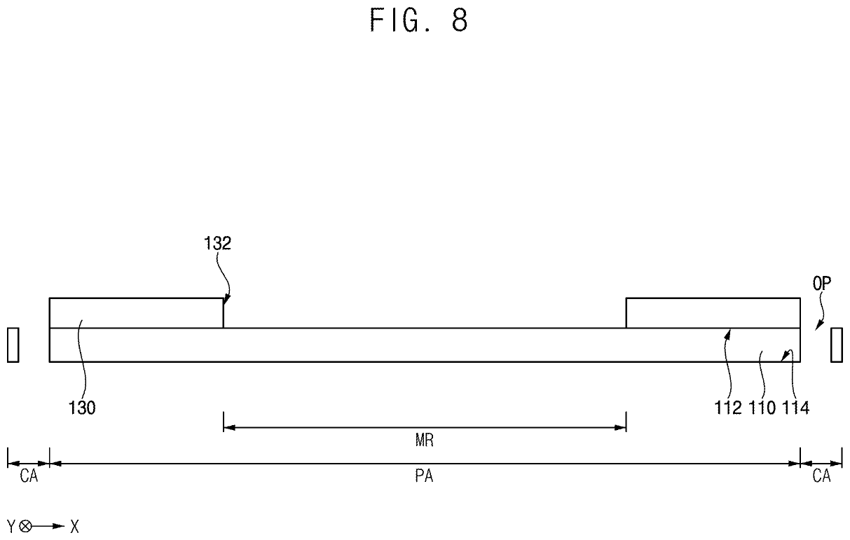

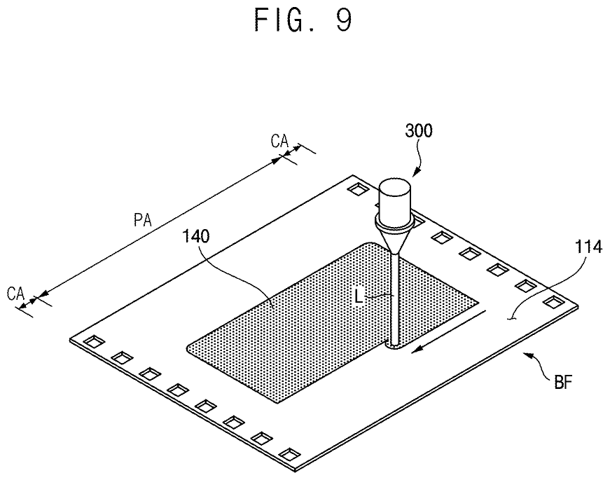

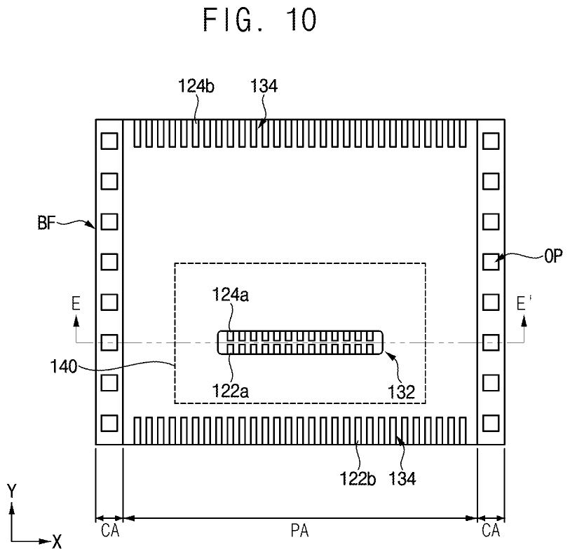

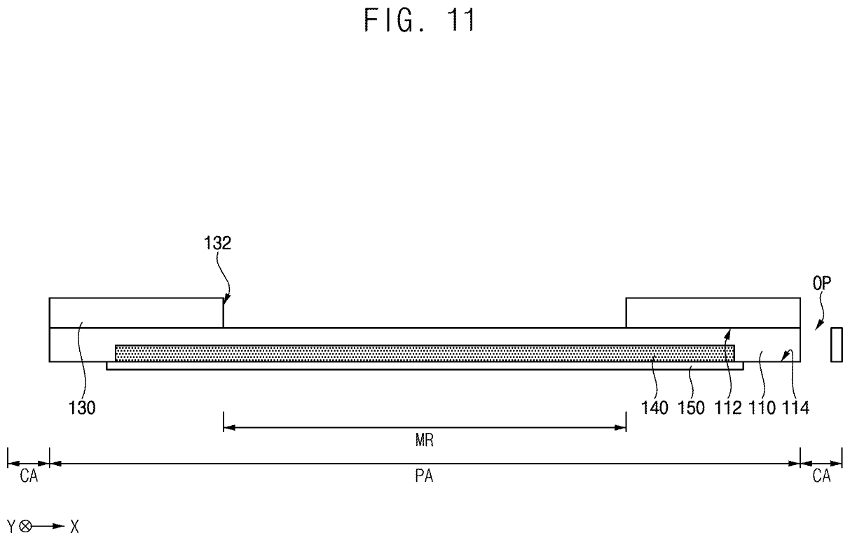

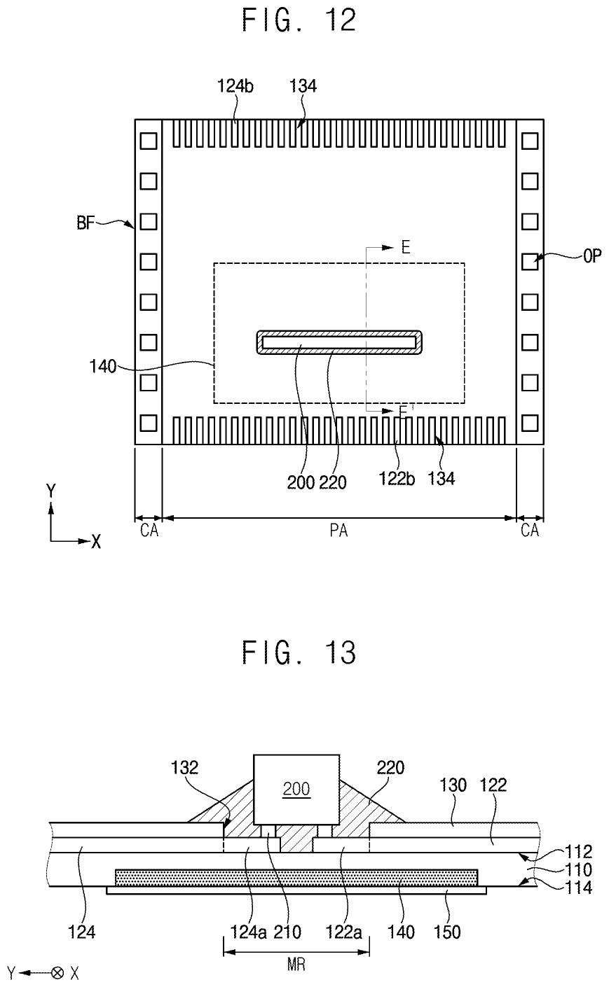

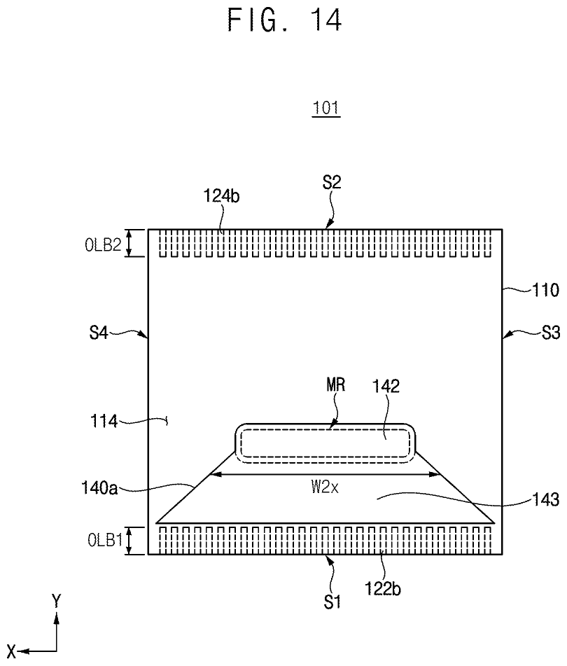

FIGS. 6 to 13 are views illustrating stages in a method of manufacturing the chip on film package 100. FIGS. 6, 10 and 12 are plan views illustrating a tab tape provided in a roll form. FIG. 7 is a cross-sectional view along line C-C′ in FIG. 6. FIG. 8 is a cross-sectional view along line D-D′ in FIG. 6. FIG. 9 is a perspective view illustrating a step of forming the heat dissipation layer 140 in the second surface 114 of the base film 110 in FIG. 6 by laser scribing. FIG. 11 is a cross-sectional view along line E-E′ in FIG. 10. FIG. 13 is a cross-sectional view along line F-F in FIG. 12.

Referring to FIGS. 6 to 8, a tape automated bonding (TAB) tape may be provided in a roll form. The TAB tape may include a flexible base film BF extending in the second direction (e.g., the Y direction).

In example embodiments, the base film BF of the TAB tape may include a package region PA extending along the extending direction (i.e., the Y direction) and cutting regions CA in both sides of the package region PA. Sprocket holes OP may be formed in the cutting regions CA to penetrate the base film. The sprocket holes OP may be spaced apart from each other along the extending direction (Y direction). The TAB tape may be wound or unwound using the sprocket holes OP. As will be described below, the cutting regions CA may be cut by a sawing process and divided into individual base films.

The package region PA of the base film BF may include the chip mounting region MR, the first outer terminal region OLB1, and the second outer terminal region OLB2. The chip mounting region MR may be located in the central portion of the base film BF and, as will be described below, may be a region where a semiconductor chip is to be mounted.

A plurality of wirings may be provided on the first surface 112 of the base film BF. The plurality of wirings may include a plurality of input wirings 122 and a plurality of output wirings 124. The input wirings 122 and the output wirings 124 may extend from the inside to the outside of the chip mounting region MR, respectively. The input wirings 122 may extend from the chip mounting region MR to the first outer terminal region OLB1 along the extending direction (Y direction) of the base film BF, i.e., in the second direction. The output wirings 124 may extend from the chip mounting region MR to the second outer terminal region OLB2 along the second direction of the base film BF. The input wirings 122 and the output wirings 124 may be spaced apart from each other along the first direction (X direction) perpendicular to the extending direction (Y direction) of the base film BF. The base film BF may correspond to the base film 110 in FIGS. 3-5 and may be used therewith interchangeably.

The input wiring 122 may include the input inner lead bonding portion 122a disposed in the chip mounting region MR and the input outer lead bonding portion 122b disposed in the first outer terminal region OLB1. The output wiring 124 may include the output inner lead bonding portion 124a disposed in the chip mounting region MR and the output outer lead bonding portion 124b disposed in the second outer terminal region OLB2.

The protective layer 130 may be coated on the first surface 112 of the base film 110 to cover at least a portion of the plurality of wirings. For example, the protective layer 130 may include a solder resist. The protective layer 130 has a mounting region opening 132 that exposes the chip mounting region MR on the first surface 112 of the base film 110 and pad openings 134 that expose at least portions of the outer lead bonding portions OLB1 and OLB2.

Thus, at least portions of the input inner lead bonding portion 122a of the input wiring 122 and the output inner lead bonding portion 124a of the output wiring 124 may be exposed by the mounting region opening 132 of the protective layer 130. At least portions of the input outer lead bonding portion 122b of the input wiring 122 and the output outer lead bonding portion 124b of the output wiring 124 may be exposed by the pad openings 134 of the protective layer 130.

In the first outer terminal region OLB1, the input outer lead bonding portions 122b of the input wirings 122 may be arranged along the first direction (X direction) to be spaced apart from each other, and in the second outer terminal region OLB2, the output outer lead bonding portions 124b of the output wirings 124 may be arranged along the first direction (X direction) to be spaced apart from each other.

Referring to FIGS. 9 to 11, the heat dissipation layer 140 may be formed on the second surface 114 of the base film 110, and the insulating layer 150 may be formed to cover the heat dissipation layer 140.

In detail, as illustrated in FIG. 9, a laser L may be irradiated onto the second surface 114 of the base film 110 to form the heat dissipation layer 140. The heat dissipation layer 140 may include a laser-induced carbon material formed on the second surface 114 of the base film 110 by laser scribing. For example, when the base film 110 includes polyimide, laser-induced grapheme (LIG), which is a three-dimensional (3D) porous graphenic material, may be formed by direct laser scribing of carbonaceous precursors.

The laser scribing, i.e., the laser irradiation of a polymer precursor, may induce photochemical and thermal conversion into graphene. The laser-induced graphene may be shaped in different 3D forms with a high surface-to-volume ratio. In addition, the laser-induced graphene may generally have high conductivity, large surface area, and resistance to strain and corrosion of graphene. Laser scribing, i.e., when irradiated with laser pulses, may transform a portion of the polymer substrate into laser-induced graphene by a photothermal pyrolysis process.

For example, polyimide (PI) films, in the form of sheets, rolls, and even adhesive tapes with a wide range of thicknesses, may be suitable precursor substrates for laser-induced graphene manufacturing. In another example, other aromatic-rich polymers, e.g., polyetheretherketone (PEEK), polyetherimide (PEI), various polysulfones (PSU) and lignin, may be used as the precursor for the laser-induced graphene.

For example, a laser processing apparatus 300 may irradiate laser pulses, e.g., a CO₂ laser or a UV excimer laser, to a target point on the second surface 114 of the base film 110. For example, the irradiation of a polyimide with a UV excimer laser, when the laser fluence is 100 mJ/cm² to 500 mJ/cm², may induce a localized heating in the target point, raising the surface temperature to about 1700° C., resulting in conversion of the polyimide at the target point to laser-induced graphene.

A proper balance between laser power and scanning speed of the laser may be important. For example, laser irradiation at a high scanning speed with low laser power may not convert polyimide to graphene, while excessive laser power and slow scanning speed may burn the substrate, e.g., the base film 110.

A suitable parameter to quantify the energy (i.e., laser power) for laser-induced graphene formation may be laser fluence (H), and the minimum laser fluence (H) required for laser-induced graphene formation may be 5 J/cm². Laser fluence (H) may be expressed by the following equation (1).

$$H = \frac{P}{v \times s \times PPI} \qquad Equation ( 1 )$$

Here, P is the laser power, v is the scanning speed of the laser, s is the spot size (e.g., area size) of the laser incident on the substrate, and PPI is the number of spots per inch. The composition and morphology of the resultant laser-induced graphene, and thus its electrical, mechanical and surface properties, may vary depending on factors, e.g., the type of laser and fabrication parameters.

As illustrated in FIGS. 10 and 11, the heat dissipation layer 140 may be formed to have a predetermined thickness T2 in a depth direction from the second surface 114 of the base film 110. The heat dissipation layer 140 may be disposed in an area overlapping the chip mounting region MR. For example, the thickness T2 of the heat dissipation layer 140 may be within a range of 10 μm to 100 μm. The heat dissipation layer 140 including the laser-induced graphene may have a thermal conductivity of 1500 W/m·K.

The insulating layer 150 may cover the heat dissipation layer 140 on the second surface 114 of the base film 110. The insulating layer 150 may cover the entire surface of the heat dissipation layer 140, e.g., the heat dissipation layer 140 may be between the insulating layer 150 and the base film 110. The insulating layer 150 may insulate the heat dissipation layer 140 and may prevent graphene particles from scattering. The insulating layer 150 may include, e.g., solder resist, polyimide, acrylic resin, epoxy resin, silicon material, etc. A thickness T3 of the insulating layer 150 may be within a range of 5 μm to 20 μm.

Accordingly, since the heat dissipation layer 140 has relatively high thermal conductivity and flexibility of the polymer, the heat dissipation layer 140 may provide higher heat dissipation characteristics, various shapes, and a high degree of design freedom, and may be prevented from being peeled off from the bent base film 110. The size, thickness and shape of the heat dissipation layer 140, the thickness of the insulating layer 150, etc. are provided as examples. The size, thickness and shape of the heat dissipation layer 140, and the thickness of the insulating layer 150 may be determined in consideration of the thickness, warpage, and heat dissipation characteristics of the entire package.

Referring to FIGS. 12 and 13, the semiconductor chip 200 may be mounted on the chip mounting region MR on the first surface 112 of the base film 110.

In example embodiments, the semiconductor chip 200 may be mounted using a flip-chip bonding method. The semiconductor chip 200 may be electrically connected to the input wirings 122 and the output wirings 124 on the first surface 112 of the base film 110 through conductive bumps 210. The conductive bumps 210 on terminals of the semiconductor chip 200 may be bonded to at least portions of the input and output inner lead bonding portions 122a and 124a exposed by the mounting region opening 132 of the protective layer 130. For example, the semiconductor chip 200 may be bonded to the input and output inner lead bonding portions 122a and 124a by a thermal compression process.

When the semiconductor chip 200 is mounted on the chip mounting region MR, the sealing member 220 may be underfilled between the semiconductor chip 200 and the base film 110. The sealing member 220 may fill the mounting region opening 132 of the protective layer 130 on the first surface 112 of the base film 110 and may be interposed between the semiconductor chip 200 and the base film 110. For example, the sealing member 220 may include an epoxy material to reinforce a gap between the semiconductor chip 200 and the base film 110.

For example, the sealing member 220 may include an epoxy molding compound (EMC). The sealing member 220 may include, e.g., an epoxy resin, a UV resin, a polyurethane resin, a silicone resin, a silica filler, etc.

Then, sawing areas between the cutting regions CA of the tab tape and the adjacent first and second outer bonding portions may be cut by a sawing process to form individual chip on film packages. Then, a display panel and the driving circuit portion 30 may be electrically connected to each other using the completed chip on film package to complete a display device.

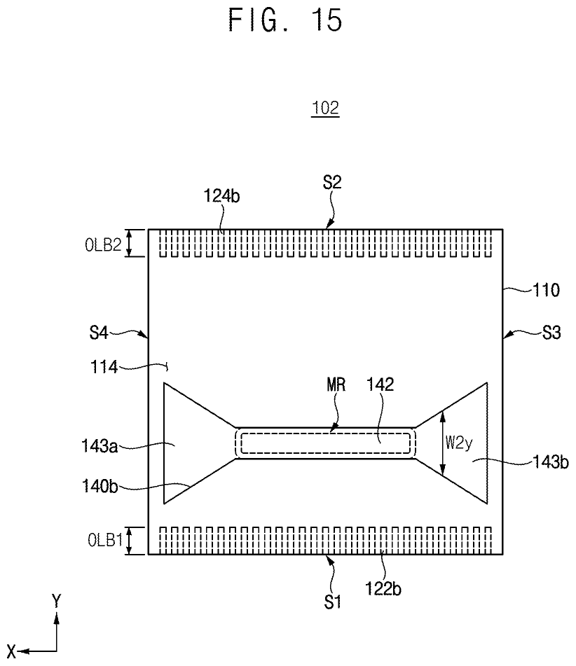

FIG. 14 is a plan view illustrating a heat dissipation layer having another shape of a chip on film package in accordance with example embodiments. FIG. 14 is a plan view illustrating the heat dissipation layer formed on a rear surface (second surface) of a base film. The chip on film package may be substantially the same as the chip on film package described with reference to FIGS. 3 to 5, except for the shape of the heat dissipation layer. Thus, same reference numerals may be used to refer to the same or like elements and any further repetitive explanation concerning the above elements will be omitted.

Referring to FIG. 14, a chip on film package 101 may include a heat dissipation layer 140a formed to have a predetermined thickness in a depth direction from the second surface 114 of the base film 110. The heat dissipation layer 140 may include a first heat dissipation portion 142 positioned in an area overlapping the chip mounting region MR and a second heat dissipation portion 143 extending from the first heat dissipation portion 142 in the extending direction (Y direction).

The second heat dissipation portion 143 may extend from the first heat dissipation portion 142 toward the first outer terminal region OLB1 (or the second outer terminal region OLB2) of the base film 110. When viewed from a plan view, a width W2x in the first direction (X direction) of the second heat dissipation portion 143 may gradually increase toward the first outer terminal region OLB1.

The first heat dissipation portion 142 may serve as a heat absorption portion that absorbs heat from the semiconductor chip mounted on the chip mounting region MR, and the second heat dissipation portion 143 may serve as a heat spreading portion that effectively spreads and dissipates the absorbed heat to the outside. Since the heat dissipation layer 140a is formed on the second surface 114 of the base film 110 by laser scribing, various shapes and high design freedom may be obtained.

FIG. 15 is a plan view illustrating a heat dissipation layer having another shape of a chip on film package in accordance with example embodiments. FIG. 15 is a plan view illustrating a heat dissipation layer formed on a rear surface (second surface) of a base film. The chip on film package may be substantially the same as the chip on film package described with reference to FIGS. 3 to 5, except for the shape of the heat dissipation layer. Thus, same reference numerals may be used to refer to the same or like elements and any further repetitive explanation concerning the above elements will be omitted.

Referring to FIG. 15, a heat dissipation layer 140b of a chip on film package 102 may include a first heat dissipation portion 142 positioned in an area overlapping the chip mounting region MR and a pair of second heat dissipation portions 143a and 143b extending from the first heat dissipation portion 142 in the first direction (X direction) perpendicular to the extending direction (Y direction).

When viewed from a plan view, a width W2y in the second direction (Y direction) of the pair of second heat dissipation portions 143a and 143b may gradually increase as a distance from the chip mounting region MR increases. The first heat dissipation portion 142 may serve as a heat absorbing portion that absorbs heat from the semiconductor chip mounted on the chip mounting region MR, and the pair of second heat dissipation portions 143a and 143b may serve as a heat spreading portion that effectively spreads and dissipates the absorbed heat to the outside.

By way of summation and review, a method of applying a large-area metal tape has been attempted to mount a semiconductor chip on a substrate, but high interfacial thermal resistance due to a multilayer film, e.g., an adhesive layer and an insulating film, may deteriorate heat dissipation characteristics. Further, when a thickness of the metal tape is supplemented to compensate for deteriorated heat dissipation characteristics, the film may be peeled off from a flexible film substrate due to an increased rigidity of the metal tape.

In contrast, example embodiments provide a chip on film package having improved heat dissipation characteristics. Example embodiments also provide a method of manufacturing the chip on film package.

That is, according to example embodiments, in a method of manufacturing a chip on film package, a flexible base film having a first surface and a second surface opposite to the first surface, having a chip mounting region, and having a plurality of wirings formed on the first surface is provided. A laser beam is irradiated on the second surface of the base film in an area overlapping the chip mounting region to carbonize a portion having a predetermined thickness in a depth direction from the second surface to form a heat dissipation layer. An insulating layer is formed on the second surface of the base film to cover the heat dissipation layer. A semiconductor chip is mounted on the chip mounting region on the first surface of the base film to be electrically connected to the plurality of wirings.

According to example embodiments, a chip on film package may include a semiconductor chip mounted on a chip mounting region on a first surface of a flexible base film, and a heat dissipation layer provided to have a predetermined thickness in a depth direction from a second surface of the base film opposite to the first surface. The heat dissipation layer may include laser-induced graphene formed in the second surface of the base film by laser scribing. Accordingly, since the heat dissipation layer has relatively high thermal conductivity and flexibility of the polymer, it may be possible to provide higher heat dissipation characteristics, various shapes, and a high degree of design freedom, and to prevent the heat dissipation layer from being peeled off from the bent base film.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A chip on film package, comprising:
a flexible base film having a first surface and a second surface opposite to the first surface, the flexible base film having a chip mounting region on the first surface;
wirings on the first surface of the flexible base film, the wirings extending from the chip mounting region in a first direction parallel to an extending direction of the flexible base film;
a semiconductor chip on the chip mounting region on the first surface of the flexible base film, the semiconductor chip being electrically connected to the wirings;
a heat dissipation layer on the flexible base film, the heat dissipation layer having a predetermined thickness in a depth direction from the second surface of the flexible base film and overlapping the chip mounting region, and the heat dissipation layer including a laser-induced carbon material; and
an insulating layer covering the heat dissipation layer on the second surface of the flexible base film.

2. The chip on film package as claimed in claim 1, wherein the flexible base film includes at least one of polyimide, polyetheretherketone, polyetherimide, polysulfone, and lignin.

3. The chip on film package as claimed in claim 1, wherein the laser-induced carbon material includes laser-induced graphene.

4. The chip on film package as claimed in claim 1, wherein the heat dissipation layer has a thickness within a range of 10 μm to 100 μm.

5. The chip on film package as claimed in claim 1, wherein a thickness of the insulating layer is within a range of 5 μm to 20 μm.

6. The chip on film package as claimed in claim 1, wherein the insulating layer includes solder resist or polyimide.

7. The chip on film package as claimed in claim 1, wherein the heat dissipation layer has a thermal conductivity of at least 1,500 W/m·K.

8. The chip on film package as claimed in claim 1, wherein the heat dissipation layer further includes an extending portion that extends from an area overlapping the chip mounting region in the first direction or in a second direction perpendicular to the first direction.

9. The chip on film package as claimed in claim 1, further comprising a protective layer covering at least portions of the wirings on the first surface of the flexible base film, the protective layer having a mounting region opening that exposes the chip mounting region.

10. The chip on film package as claimed in claim 9, wherein the semiconductor chip is mounted on portions of the wirings exposed by the mounting region opening of the protective layer via conductive bumps.

11. A chip on film package, comprising:
a flexible base film having a chip mounting region, the flexible base film having a first surface and a second surface opposite to each other, and the flexible base film extending in a first direction;
wirings on the first surface of the flexible base film, each of the wirings having an inner lead bonding portion in the chip mounting region;
a protective layer covering at least portions of the wirings on the first surface of the flexible base film, the protective layer having a mounting region opening that exposes the chip mounting region;
a semiconductor chip on the chip mounting region on the first surface of the flexible base film and mounted on the inner lead bonding portions via conductive bumps;
a heat dissipation layer having a predetermined thickness in a depth direction from the second surface of the flexible base film in an area overlapping the chip mounting region, the heat dissipation layer including a laser-induced carbon material; and
an insulating layer covering the heat dissipation layer on the second surface of the flexible base film.

12. The chip on film package as claimed in claim 11, wherein the flexible base film includes at least one of polyimide, polyetheretherketone, polyetherimide, polysulfone, and lignin.

13. The chip on film package as claimed in claim 11, wherein the laser-induced carbon material includes at least one of laser-induced graphene, laser-induced graphite, and laser-induced carbon nanotubes.

14. The chip on film package as claimed in claim 11, wherein a thickness of the heat dissipation layer is within a range of 10 μm to 100 μm.

15. The chip on film package as claimed in claim 11, wherein the heat dissipation layer has a thermal conductivity of at least 1,500 W/m·K.

16. The chip on film package as claimed in claim 11, wherein a thickness of the insulating layer is within a range of 5 μm to 20 μm.

17. The chip on film package as claimed in claim 11, wherein the insulating layer includes solder resist or polyimide.

18. The chip on film package as claimed in claim 11, wherein the heat dissipation layer further includes an extending portion that extends from an area overlapping the chip mounting region in the first direction or in a second direction perpendicular to the first direction.

19. The chip on film package as claimed in claim 11, further comprising a sealing member between the semiconductor chip and the base film and filling the mounting region opening of the protective layer.

20. A chip on film package, comprising:
a flexible base film having a first surface and a second surface opposite to the first surface, the flexible base film extending in a first direction and having a chip mounting region that extends in a second direction perpendicular to the first direction, and the flexible base film having a first side surface and a second side surface extending in a direction parallel to the second direction and facing each other;
wirings on the first surface of the flexible base film, each of the wirings including an inner lead bonding portion in the chip mounting region and an outer lead bonding portion in at least one of the first side surface and the second side surface;
a protective layer covering at least portions of the wirings on the first surface of the flexible base film, the protective layer having a mounting region opening that exposes the chip mounting region and pad openings that expose the outer lead bonding portions;
a semiconductor chip on the chip mounting region on the first surface of the flexible base film and mounted on the inner lead bonding portions via conductive bumps;
a sealing member filling the mounting region opening of the protective layer and interposed between the semiconductor chip and the flexible base film;
a heat dissipation layer having a predetermined thickness in a depth direction from the second surface of the base film in an area overlapping the chip mounting region, the heat dissipation layer including a laser-induced graphene; and
an insulating layer covering the heat dissipation layer on the second surface of the base film.
